(19) United States
(12) Patent Application Publication
(10) Pub. No.: US 2001/0004716 A1
(43) Pub. Date: Jun. 21, 2001

(54) Apparatus for reading sounds, particularly recorded, that can be mounted on a vehicle

(76) Inventor: Lyes Seba, Paris (FR)

Correspondence Address: YOUNG & THOMPSON, 745 SOUTH 23RD STREET 2ND FLOOR, ARLINGTON, VA, 22202

(21) Appl. No.: 09/725,121

(22) Filed: Nov. 29, 2000

(30) Foreign Application Priority Data
Nov. 29, 1999 (FR) 99/15029

(51) Int. Cl. G06F 17/00; H03G 3/00; G10L 11/00

(52) U.S. Cl. 700/94; 381/86; 369/31; 381/61; 704/270; 704/272; 704/278

(57) ABSTRACT

The invention relates to a portable apparatus or an apparatus mounted on a vehicle, for reading sounds recorded on supports, either according to an analog process on magnetically recorded supports, which is to say on cassettes, or according to a digital process on compact discs, comprising at least one reading assembly for the recordation supports and a broadcast assembly of sounds comprising an amplifier and at least one restitution element of sounds such as a loudspeaker.

The apparatus is characterized in that it comprises on the one hand a reading assembly (10) comprising at least one reader with the unit (11-12) of numerous different recordation supports, namely a cassette reader (11) and/or a compact disc reader (12), and on the other hand a digital mass memory (30) whose input is connected to the output of the or each reader (11-12) so that it can receive and store digital sounds already recorded on numerous different supports and broadcast with the unit, the apparatus comprising moreover, if necessary, an analog/digital converter (31), located between the output of a reader (11) of the analog type and the digital mass memory (30), which is interposed between the assembly of the reader (10) and the broadcast element (20).

Apparatus for reading recorded sounds, comprise a reader properly so called, of discs, cassettes, compact discs or mini discs.

Conventional discs of 15 to 30 centimeters in diameter, require disc turntables that are very cumbersome and are used only in places offering all of the space necessary, both for the apparatus and for the discs themselves in more or less great number.

When such apparatus must be mounted on vehicles, the volume that they occupy is a fundamental given, and the room to store the records (discs or magnetic tapes) is absolutely critical. But size is not the only thing, because the situation of the user is not at all the same as in home as in a vehicle.

Thus, in a home, it is not necessary that the user be in a fixed place, nor be practically immobilized, nor have to concentrate on a vital task.

On the contrary, in a vehicle, in particular in an automobile, it is necessary that the user remain seated and be very limited in his movements and if he drives the vehicle he must moreover exercise extreme vigilance, his eyes on the road, to say nothing of the additional task imposed by the steering wheel.

It is thus extremely important that the control of the sound system of the vehicle be as simple as possible, and manufacturers seek to render the operations as automatic as possible. The radio receiver, for example, is at present associated with automatic location systems for local stations, or type of emission, etc.

As to the recording media, it is impossible to avoid a minimum number of manipulations.

As to compact discs, it is necessary only to fit them, one by one, into a slot, their emplacement taking place automatically, without other intervention by the user. The end of their program also brings them automatically to a stop and to withdraw them, it suffices to push on a button to cause their appearance over a fraction of their surface sufficient to grasp them.

In the case of cassettes, it is necessary to place them one by one into a recess protected by a freely pivoting flap and often to actuate a start button. As the end of the program they do not necessarily stop if the apparatus is provided with an “auto reverse” system, which connects the two surfaces of the magnetic tape.

But the really serious problem which arises in connection with discs as in connection with cassettes, is their filing and the manipulations indispensable for extracting them and filing them, particularly if the user is careful and desires to replace the disc in its case or the cassette in its housing.

To simplify these difficult and dangerous manual operations, there have been provided disc changers which are relatively cumbersome apparatus and cannot be placed in the dashboard of the vehicle where it would take up a good deal of space, or in the glove box which it would practically entirely occupy.

The installation of such a changer is in any event complicated, particularly because the connection between the sound box (radio and at least one reader) and the distant changer takes place not simply by wire but by an optical fiber conductor, which imposes often severe constraints because it is necessary to maintain a minimum radius of curvature, to avoid pinching, etc., which requires the intervention of qualified personnel who are well trained.

Moreover, the discs must be emplaced in a loader which has a limited capacity, such that if the user desires while driving to listen to a disc which has not first been placed in the loader, or else he wishes to replace the discs to which he has listened, with others, he is obliged to stop the vehicle, get out, open the trunk, take out the baggage to reach the disc changer, withdraw the discs from the loader and replace them with others, which supposes the filing of the first and the withdrawal of the second from their arranged position, then replacing the baggage, etc.

As to cassettes, their construction itself and their mode of reading have not until now permitted providing a practical loader because it would be necessary in addition to assembling the reader, starting, stopping, replaying, when different cassettes are desired.

The miniaturization of compact discs has led to mini discs whose diameter is but several centimeters, but these discs do not change the fundamentals of the situation which has been described.

Moreover, apparatuses known of the dictaphone type, whose circuit comprises analog/digital converters and digital/analog converters, and particularly:

U.S. Pat. No. 5,923,624 which describes a dictaphone having been combined with an autoradio and comprising, for this purpose, a microphone for dictation and a recording assembly of known type. The apparatus comprises two separable portions of which one is called “removable operational portion” without which the autoradio could not operate (column 3, lines 11-12).

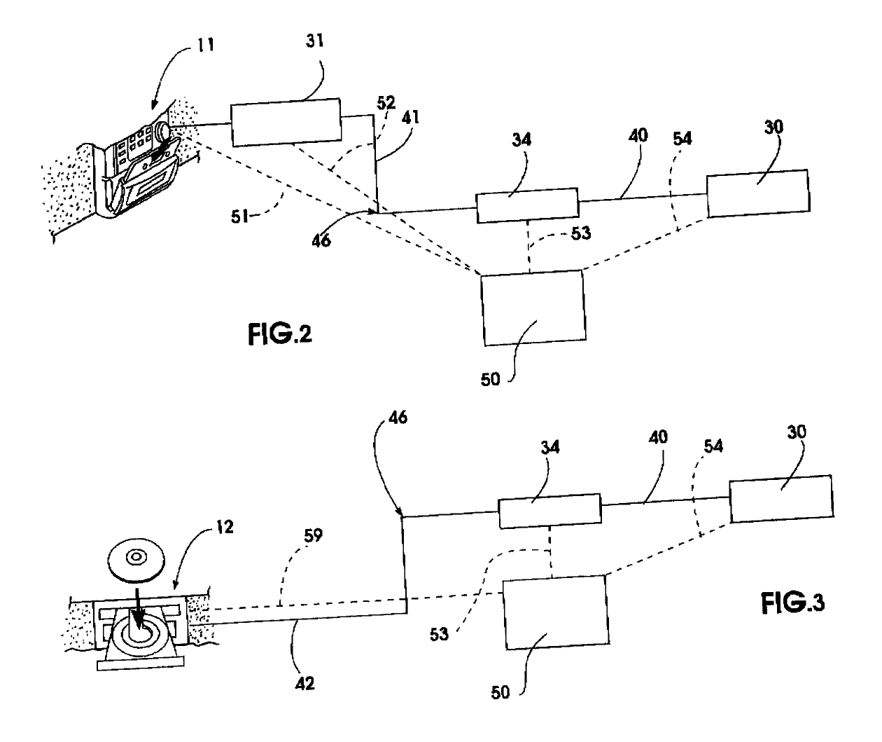

The autoradio has no reader of its recorded sounds, the connection between the decoder 24 and the digital memory 12 shown in FIG. 2 serves only to record messages emitted digitally and of a particular type such as is known under the name “ARI” which communicates spoken information concerning a field previously selected by the listener (sports, news, etc.)

The analog memory has a very small capacity which is measured in minutes of listening (column 3, lines 42-49) which shows that the invention is applicable exclusively to the control of speech, whether it be recorded very occasionally from brief messages received from an antenna, or whether it have been dictated by the user himself in the “operational portion” separated from the autoradio;

EP 1 001 428 which describes a dictaphone comprising a microphone and a recording assembly incorporating a system of signal compression. This invention does not relate to the control of the mass memory for recorded data, in an apparatus having no microphone;

U.S. Pat. No. 6,061,306, which relates to a cassette comprising an emulator permitting rendering compatible with an analog reading head, data stored in digital form.

This arrangement has no point in common with the present invention.

The present invention provides a new solution which is substantially different from the elements known in the prior art and which gives freedom from all the individual manipulations of the recording supports.

To this end, the invention has for its object a portable apparatus or an apparatus mounted on a vehicle, for reading sounds recorded on supports, either according to an analog process on magnetically recorded supports, which is to say in cassettes, or according to a digital process on compact discs, comprising at least one assembly for reading the recordation supports and an assembly for broadcasting sounds comprising an amplifier and at least one restitution element for sounds such as a loudspeaker, characterized in that it comprises on the one hand a reading assembly comprising at least one reader with the unit of numerous different recordation supports, namely a cassette reader and/or a reader of compact discs, and on the other hand a digital mass memory whose input is connected to the output of the or each reader so that it can receive and store digital sounds already recorded on numerous different supports and broadcast with the unit, the apparatus comprising moreover, if necessary, an analog/digital converter located between the output of an analog type reader and the digital mass memory, which is interposed between the reading assembly and the broadcast element.

The invention will be better understood from the detailed description hereafter, given with reference to the accompanying drawing. Of course, the description and the drawing are given only by way of indicative example and are not limiting.

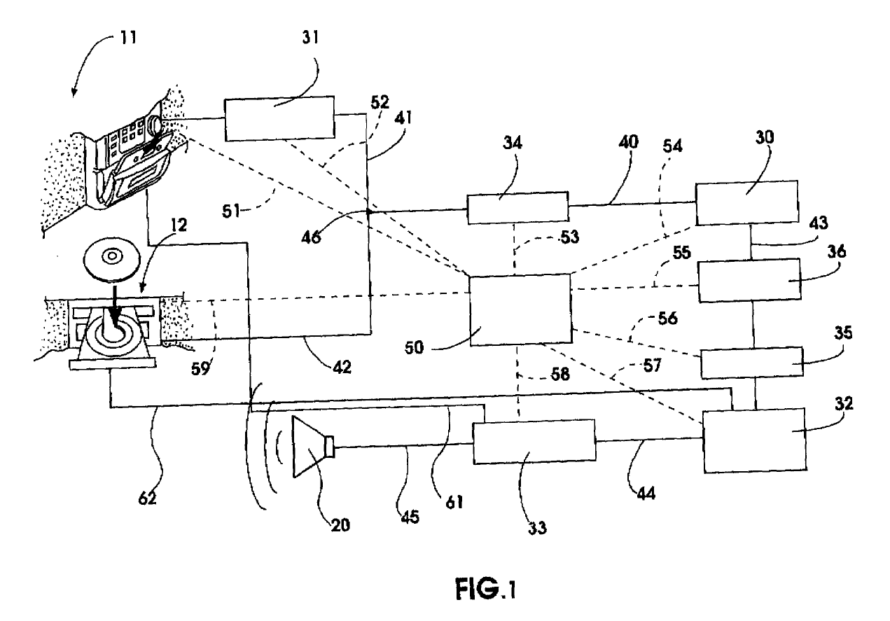

FIG. 1 is a general diagram of an apparatus according to the invention, comprising a cassette reader and a compact disc reader.

FIG. 2 is a diagram corresponding to the use only of the cassette reader.

FIG. 3 is a diagram corresponding to the use only of the compact disc reader.

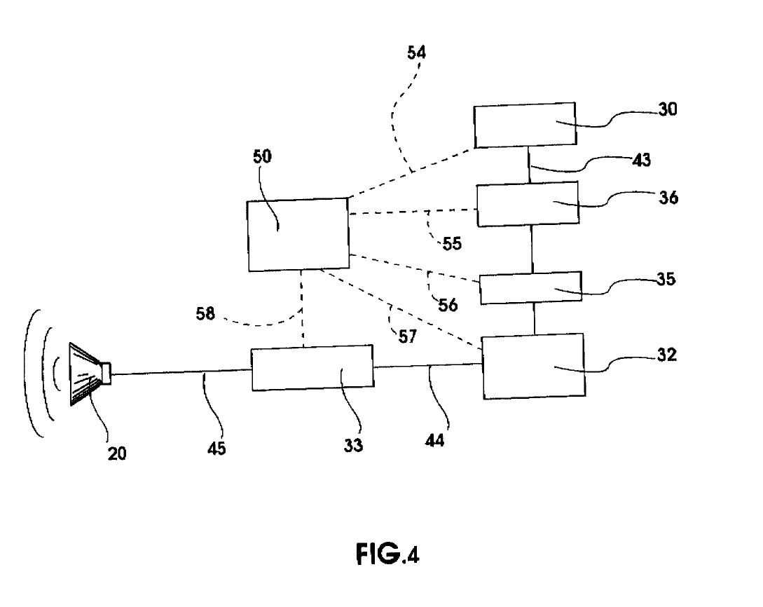

FIG. 4 is a diagram corresponding only to listening to a digital memory.

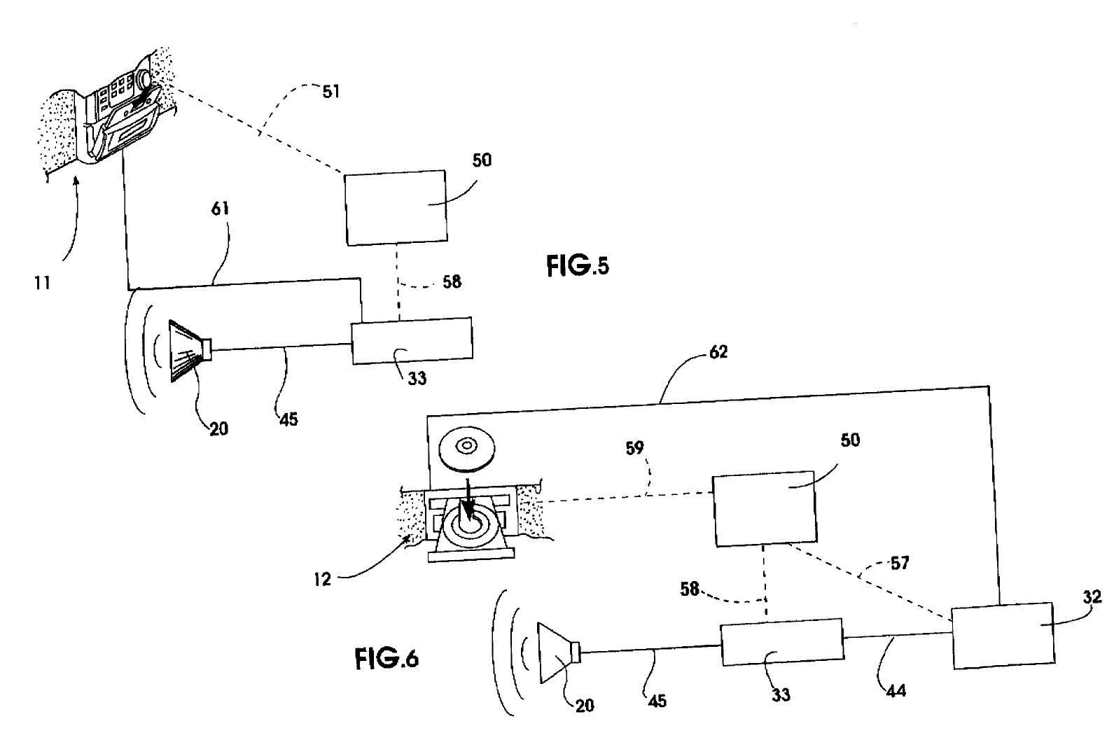

FIG. 5 is a diagram corresponding to direct listening from a cassette disposed in the reader.

FIG. 6 is a diagram corresponding to the direct reading of a compact disc placed in the reader.

Referring to the diagram of FIG. 1, there is seen an apparatus according to the invention comprising a cassette reader 11 of any known type per se and a compact disc reader 12 also of any known type, both if desired combined with a radio receiver, these devices constituting together, whatever their number, a reading assembly 10.

The reading assembly 10 is of course associated with a control panel (not shown) comprising control buttons corresponding to the different functions of the different readers, and to a broadcast assembly 20 symbolized here by a simple loudspeaker but which, in reality, could be more complicated and in particular be comprised of several chambers if desired incorporated in elements of the passenger space of the vehicle.

The complete circuit of the apparatus comprises a digital memory 30 to which leads an input conductor 40 to which lead to respective conductors 41 from the cassette reader 11, and 42 from the compact disc reader 12.

The electrical signals of the cassette reader 11 are analogic and must thus be converted into digital signals to be able to be introduced into the memory 30, for which reason an analog/digital converter 31 is interposed in the conductor 40, whilst such a converter is useless for reading compact discs because the electrical signals which it emits are digital in nature.

To the digital memory 30 is connected an output conductor 43 leading to a digital/analog converter 32, itself connected by a conductor 44 to an amplifier 33 connected to the broadcast assembly 20 by a conductor 45.

So as to be able to store a large number of data in the digital memory 30, any compressor 34 of known type is interposed in the conductor 40, between the junction point 46 of the conductors 41-42 and the input of the digital member 30.

The memorized data having been compressed, it is necessary to decompress them at the output of the digital memory 30, before entering the digital/analog converter 32, hence the presence of a decompressor 35 of known type disposed in the conductor 43.

Because of the inevitable jolts, shocks, vibrations and acceleration/deceleration to which the vehicle is subject, it is preferable to provide a digital buffer memory 36 at the output of the digital memory 30 because, to the extent there is here used a method known to those skilled in the art for known direct reading apparatus, there is created an initial delay between the emission of the output signals of a reader and their broadcast, by temporary storage in a buffer memory for the output signals, such that the sound diffused is emitted not from the direct reader but from the buffer memory, and any reading incident is eliminated because there is no retention in the buffer memory.

The same is true here, not with a sound reader, but with the digital memory 30, as will be seen from the following operation.

The assembly of the installation is supervised by a controller 50 of known type having connections 51 to 59 respectively, with the cassette reader 11, with the analog/digital converter 31, with the compressor 34, with the digital memory 30, with the buffer memory 36, with the decompressor 35, with the digital/analog converter 32, with the amplifier 33 and with the compact disc reader 12.

Moreover, two conductors 61 and 62 ensure direct connection on the one hand between the reader 11 and the amplifier 33, and on the other hand between the reader 12 and the digital/analog converter 32.

The operation of the apparatus whose assembly diagram has been described is different according to the various possibilities offered to the user and which are specific to the invention, because no apparatus now known can perform these. There will now be described this operation according to the different possibilities:

1. Committing to Memory the Content of a Cassette without Simultaneous Playing

FIG. 2 shows the corresponding circuit which permits transferring output signals from the reader 11 to the converter 31, to the compressor 34, then introducing them into the digital memory 30.

When the user is not listening to what he is recording, it is possible to include in the apparatus of the invention a reading accelerator, permitting high speed commitment to memory.

It is possible also to proceed to this recording without listening, whilst listening to another sound source such as the radio.

2. Commitment to Memory of the Content of a Compact Disc without Simultaneous Listening

FIG. 3 shows the corresponding circuit which permits transferring output signals from the reader 12 to the compressor 34, then introducing them into the digital memory 30.

When the user does not listen to what he is recording, it is possible to include in the apparatus of the invention a reading accelerator, permitting commitment to memory at high speed.

It is possible also to perform this recording without listening, whilst listening to another sound source such as the radio.

3. Listening to Data Previously Stored in the Memory 30

FIG. 4 show the corresponding circuit which permits accessing data from the memory 30, via the buffer memory 36, the decompressor 35, the digital/analog converter 32, the amplifier 33 and the broadcast assembly 20.

4. Direct Listening to Data from a Cassette, without Memorization

FIG. 5 shows the corresponding circuit, by which the electrical signals from the reader 11 are directly sent to the amplifier 33, without passing through the memory circuit 30 and its supplements.

It will be understood that this is equivalent to a standard apparatus, the controller 50 establishing this circuit by selection from among the other solutions offered by the complete circuit.

5. Direct Listening to Data from a Compact Disc, without Memorization

FIG. 6 shows the corresponding circuit, by which electrical signals from the reader 12 are sent by the conductor 62 to the digital/analog converter 32, then to the amplifier 33, without passing through the memory circuit 30 and its supplements.

It will be understood that this is equivalent to a standard apparatus, but here the controller 50 establishes this circuit by selection from among the other solutions offered by the complete circuit.

However, it must be emphasized that any apparatus comprising a reader using the digital technology (compact discs or the like) has an integrated outlet converter without which a loudspeaker, which is of the analog type, could not restore to the human year sounds corresponding to those which have been recorded.

This illustrates the fact that the invention can have various embodiments according to whether it is applied to an assembly comprising standard readers provided with converters, with amplifiers and/or with a pre-existing broadcast assembly, and added to a circuit according to the invention, or else whether the invention, on the contrary, gives rise to the provision of a new apparatus.

It is thus that the invention can be manifested by an independent housing connected to an autoradio comprising a radiophonic receiver and at least one reader (cassettes, compact discs, mini discs), everything disposed in the standard recess existing on an automobile, the sound reproduction assembly forming a part itself of the standard equipment of the automobile or being pre-installed but independently of the apparatus comprising the invention.

6. Memorization of the Content of a Recordation Support with Simultaneous Listening

This is very probably the best solution for a user having a new cassette or a new compact disc, because he would certainly desire to listen to what is being memorized or, which is the same thing, to record what he hears.

There has not been shown the specific diagram for this use, because it is a simple combination of the diagrams of FIGS. 2 and 5 for the reader 11, and a combination of the diagrams of FIGS. 3 and 6 for the reader 12.

It will be seen from the above description, that it is thenceforth possible to eliminate purely and simply all the recording supports in a vehicle, or more generally in any place where this is desired, after they have been memorized.

Thus, a user can keep all the recording supports at his home after having recorded them, which avoids the present dilemma of deciding whether such and such a disc must be kept at home or in the car.

It also becomes useless to provide a disc changer in the glove box, and to keep more or less handy the disc or cassette libraries in the car.

Thus, in addition to avoiding all mechanical wear and tear on the disc changers, there is the advantage of the remarkable rapidity of the electronics because a disc changer gives rise to a delay of 8 to 10 seconds between two discs; whilst with the invention, the passage of one recording to another can be almost instantaneous, and in any case without any time difference existing between two recordings on a same disc and two recordings belonging to two different discs and memorized at different times.

It will also be understood that the memorization of the records permits keeping these records in a new condition because they can be listened to as many times as desired without further touching them. When the records are kept in the vehicle, they are not only subjected to the wear of their normal use but moreover are subjected to high temperature, dirt, shocks and the handling which the invention totally eliminates.

This great ease of use can lead to the application of the invention not only in apparatus mounted on vehicles but also for use at fixed positions.

The invention also renders possible the provision of digital memories 30 that are removable and hence interchangeable, each having a collection of musical pieces that if desired can be specialize: rock, dance, classical, etc.

Such a memory can easily contain all the compact discs representing a collection such as all the songs of a same performer or a same composer. Thus, for example, a memory 30 of 4 giga octets can contain the equivalent of about 100 compact discs, according to the exact duration of each of them and according to the degree of compression selected. This capacity is to be compared to that of disc changers, which at present is a maximum of 10 compact discs and very rarely 12.

Naturally, it is possible to use the invention not only with records but also with a radio receiver or else with a microphone for the direct recordation of the human voice or for sonic reporting.

Given the large capacity of digital memories, especially associated with a compressor/decompression system for the signal, the invention provides that the user can as desired introduce signals between the different recorded pieces, so as to be able to retrieve them selectively.

These signals are digital signals from an electronic circuit specific to the invention, controlled by a keyboard, or vocally as will be explained.

There are known digital signals called “CD TEXT” but this is a technology used by apparatus reserved for professionals and which is not compatible with the very small size required by an apparatus according to the invention, adapted to be contained in a housing or the format of standard autoradios.

Moreover, these signals are recorded definitively on the disc and not disposed in a modifiable memory, contrary to the invention.

The electronic assembly specific to the emission of these signals (or reference points) must be connected to the controller 50 so that the user will be able to introduce into the memory 50 in a coordinated manner with the signals placed in the memory, which is to say the user selects the reference points as a function of the recording and can modify them as he can erase and replace recordings already memorized.

Modern autos have a display screen often associated with a computer, and it is thus easy to design an apparatus incorporating the present invention and to ensure the display of interesting data, particularly the references placed by the user between recorded pieces, so that the user can scroll the list of the different recordings memorized, to select them, even to selectively erase them and replace them.

Under conventional keyboard control, there can be substituted or added a vocally actuated control comprising a detector, which is to say a microphone, and a transducer transforming the speech or sounds of the user into electrical signals, as well as an analog/digital converter to place in the memory 50 sounds directly emitted by the user which can thus give the title of a piece of music, or introduce other commentaries, either immediately audible and comprehensible, or else inaudible.

However, it must be understood that the apparatus according to the invention is totally independent of any computer t if reference is had above to the presence of an onboard computer, it is solely to take advantage of facilities available for the production of reference marks between the memorized recordings. Thus, it is also possible to create such reference marks without any computer, particularly by emission of vocal messages.

1. Portable apparatus or apparatus mounted on a vehicle, for reading sounds recorded on supports, either according to an analog process on magnetically recorded supports, which is to say on cassettes, or according to a digital process on compact discs, comprising at least one assembly for reading the recorded supports and a broadcast assembly of sounds comprising an amplifier and at least one sound restitution element such as a loudspeaker, characterized in that it comprises on the one hand a reading assembly (10) comprising at least one reader with the unit (11-12) of numerous different recording supports, namely a cassette reader (11) and/or a compact disc reader (12), and on the other hand a digital mass memory (30) whose input is connected to the output of the or each reader (11-12) so that it can receive and store digital sounds already recorded on numerous different supports and broadcast with the unit, the apparatus moreover comprising, if necessary, an analog/digital converter (31), located between the output of the reader (11) of analog type and the digital mass memory (30), which is interposed between the reading assembly (10) and the broadcast element (20).

2. Apparatus according to claim 1, characterized in that the original sounds being of the analog type, the apparatus comprises on the one hand an analog/digital converter (31) interposed between the reading assembly (10) and the digital mass memory (30), and on the other hand a digital/analog converter (32) disposed at the input of the amplifier (33) to which the broadcast element (20) is connected.

3. Apparatus according to claim 1, characterized in that it comprises on the one hand a data compressor (34) disposed at the input of the digital mass memory (30) and on the other hand a decompressor (35) disposed at the output of said memory (30).

4. Apparatus according to claim 1 characterized in that a buffer memory (36) is disposed between the digital mass memory (30) and the broadcast assembly (20).

5. Apparatus according to claim 1, characterized in that it comprises a controller (50) and/or control means adapted to connect directly the assembly of the reader (20) to the amplifier (33) , without intervention of the digital mass memory (30).

6. Apparatus according to claim 1, characterized in that it comprises an assembly for emitting digital signals connected to the controller (50) for the introduction of such digital signals into the digital mass memory (30), in a manner coordinated with those which come from the reading assembly (10), for arranging in the memory, classification and selection.

7. Apparatus according to claim 6, characterized in that the emission assembly for digital signals comprises a vocal control device comprising a detector of sounds and a transducer, so that the signals will be issued from messages emitted vocally by the user.
